(19) United States
(12) Patent Application Publication
(10) Pub. No.: US 2026/0175742 A1
(43) Pub. Date: Jun. 25, 2026

(54) AVAILABLE POWER OUTPUT DETERMINATION APPARATUS AND METHOD OF FUEL CELL STACK

(71) Applicants: Hyundai Motor Company, Seoul (KR); Kia Corporation, Seoul (KR)

(72) Inventors: Jae Won Jung, Hwaseong-Si (KR); Jae Won Jang, Hwaseong-Si (KR); Seong Ik Jang, Hwaseong-Si (KR)

(21) Appl. No.: 19/245,866

(22) Filed: Jun. 23, 2025

(30) Foreign Application Priority Data
Dec. 23, 2024 (KR) 10-2024-0193640

(51) Int. Cl. B60L 58/30; B60L 50/70; G01R 31/40; H01M 8/04537; H01M 8/04992

(52) U.S. Cl. CPC B60L 58/30; B60L 50/70; G01R 31/40; H01M 8/04559; H01M 8/04589; H01M 8/04619; H01M 8/04992; H01M 2250/20

(57) ABSTRACT

An apparatus for determining available power output of a fuel cell stack may include a processor a memory. The apparatus may measure, in real-time during an operation of a fuel cell stack comprising a plurality of cells, a current value and a voltage value associated with the fuel cell stack; determine at least one parameter of the fuel cell stack by applying the measured current value and the measured voltage value to a current-voltage characteristic model; determine, based on applying the at least one parameter to the current-voltage characteristic model and based on an available voltage value of the fuel cell stack, an available power output of the fuel cell stack; and control, based on the available power output of the fuel cell stack, an operation of the fuel stack.

### CROSS-REFERENCE TO RELATED APPLICATION

This application claims priority to Korean Patent Application No. 10-2024-0193640, filed on Dec. 23, 2024, the entire contents of which are incorporated herein by reference.

### TECHNICAL FIELD

The present disclosure relates to a fuel cell stack, and more specifically to an available power output determination apparatus of a fuel cell stack.

### BACKGROUND

To determine the degree of deterioration in performance of a fuel cell stack and to accurately determine a cause of the deterioration, a voltage loss and resistance characteristics of the fuel cell stack may be measured. Resistance measurement using alternating impedance, high frequency resistance (HFR) measurement using an alternating milliohm meter, and ohmic resistance measurement using current isolation are widely used to measure the resistance characteristics of the fuel cell stack or cells.

The above information disclosed in this Background section is only for enhancement of understanding of the background of the disclosure and therefore it may contain information that does not form prior art already known to a person of ordinary skill in the art.

### SUMMARY

The present disclosure has been made in an effort to solve problems found in at least some implementations. An object of the present disclosure is to provide an available power output determination apparatus of a fuel cell stack and an available power output determination method of a fuel cell stack, capable of predicting a current-voltage characteristic model of each of cells that form the fuel cell stack to accurately determine a voltage state of the fuel cell stack and determine a limited current value of the fuel cell stack and an available power output according to the limited current value.

According to one or more example embodiments of the present disclosure, an apparatus may include a processor and a memory. The memory may store at least one instruction that is configured, when executed by the processor communicating with the memory, to cause the apparatus to: measure, in real-time during an operation of a fuel cell stack including a plurality of cells, a current value and a voltage value associated with the fuel cell stack; determine at least one parameter of the fuel cell stack by applying the measured current value and the measured voltage value to a current-voltage characteristic model; determine, based on applying the at least one parameter to the current-voltage characteristic model and based on an available voltage value of the fuel cell stack, an available power output of the fuel cell stack; and control, based on the available power output of the fuel cell stack, an operation of the fuel stack. The voltage value may include at least one of an average voltage value of the plurality of cells or a minimum voltage value of the plurality of cells.

The available voltage value may include one of: based on the available power output being determined using the average voltage value, a first available voltage value that is applied to the current-voltage characteristic model; or, based on the available power output being determined using the minimum voltage value, a second available voltage value that is applied to the current-voltage characteristic model.

The at least one instruction may be configured, when executed by the processor communicating with the memory, to cause the apparatus to determine the available power output of the fuel cell stack by: based on the at least one parameter being determined based on the average voltage value, determining a first available current value of the fuel cell stack by applying the first available voltage value to the current-voltage characteristic model; or, based on the at least one parameter being determined based on the minimum voltage value, determining a second available current value of the fuel cell stack by applying the second available voltage value to the current-voltage characteristic model.

The at least one instruction may be configured, when executed by the processor communicating with the memory, to cause the apparatus to determine the available power output of the fuel cell stack by using a lesser value of the first available current value and the second available current value.

The at least one parameter may include at least one of an activation loss parameter or an ohmic loss parameter.

The at least one instruction may be configured, when executed by the processor communicating with the memory, to further cause the apparatus to: determine the activation loss parameter by applying a first current value and a first voltage value that are measured in a low current section of the current-voltage characteristic model; and determine the ohmic loss parameter by applying a second current value and a second voltage value that are measured in a normal current section of the current-voltage characteristic model. A first minimum current value of the low current section may be less than a second minimum current value of the normal current section.

An equation for determining the activation loss parameter may use a predetermined ohmic loss parameter as a variable. An equation for determining the ohmic loss parameter may use a predetermined activation loss parameter as a variable.

The current-voltage characteristic model may include an equation:

$$V = {V}_{ocv} - B \times In ( I ) - R \times I$$

where V represents the voltage value, V_{ocv} represents a constant, B represents an activation loss parameter, I represents the current value, and R represents an ohmic loss parameter.

The at least one instruction may be configured, when executed by the processor communicating with the memory, to further cause the apparatus to: based on the activation loss parameter, the ohmic loss parameter, and a plurality of historical current values, perform linearization of the current-voltage characteristic model; and determine an available current value by determining a maximum value among a plurality of preliminary current values. The plurality of preliminary current values may be determined by applying the available voltage value to the linearized current-voltage characteristic model.

According to one or more example embodiments of the present disclosure, a method performed by an apparatus associated with a fuel cell stack may include: measuring, via a voltage sensor and during an operation of the fuel cell stack, an average voltage value of a plurality of cells of the fuel cell stack and a minimum voltage value of at least two of the plurality of cells; determining a first parameter of the fuel cell stack by applying the measured average voltage value to a current-voltage characteristic model of the fuel cell stack; determining a second parameter of the fuel cell stack by applying the measured minimum voltage value to the current-voltage characteristic model; identifying, based on at least one of the first parameter or the second parameter and based on the current-voltage characteristic model, an available power output of the fuel cell stack; and controlling, based on the available power output of the fuel cell stack, an operation of the fuel cell stack.

The first parameter may include an activation loss parameter. The second parameter may include an ohmic loss parameter.

Determining the first parameter may include: determining the activation loss parameter by applying, to the current-voltage characteristic model, a first average voltage value and a first minimum voltage value that are measured in a low current section of the current-voltage characteristic model. Determining the second parameter may include determining the ohmic loss parameter by applying, to the current-voltage characteristic model, a second average voltage value and a second minimum voltage value that are measured in a normal current section of the current-voltage characteristic model. A first minimum current value of the low current section may be less than a second minimum current value of the normal current section.

Determining the available power output of the fuel cell stack may include: determining a first available current value of the fuel cell stack based on: the current-voltage characteristic model, to which the first parameter is applied, and a first available voltage value; and determining a second available current value of the fuel cell stack based on: the current-voltage characteristic model, to which the second parameter is applied, and a second available voltage value.

Determining the available power output of the fuel cell stack may further include: determining the available power output of the fuel cell stack by using a lesser value of the first available current value and the second available current value.

Determining the available power output of the fuel cell stack may further include: performing, based on a plurality of historical current values, linearization of the current-voltage characteristic model; determining a plurality of first preliminary current values by applying the first available voltage value to the linearized current-voltage characteristic model; determining a plurality of second preliminary current values by applying the second available voltage value to the linearized current-voltage characteristic model; determining the first available current value by determining a first maximum value among the plurality of first preliminary current values; and determining the second available current value by determining a second maximum value among the plurality of the second preliminary current values.

According to one or more example embodiments of the present disclosure, a vehicle may include: at least one sensor including a voltage sensor; a fuel cell stack including a plurality of cells; a processor; and a memory storing at least one instruction that is configured, when executed by the processor communicating with the memory, to cause the vehicle to: measure, during an operation of the fuel cell stack, a current value and a voltage value associated with the fuel cell stack; determine at least one parameter of the fuel cell stack by applying the measured current value and the measured voltage value to a current-voltage characteristic model; determine, based on applying the at least one parameter to the current-voltage characteristic model and based on an available voltage value of the fuel cell stack, an available power output of the fuel cell stack; and control, based on the available power output of the fuel cell stack, an operation of the fuel cell stack. The voltage value may include at least one of an average voltage value of the plurality of cells or a minimum voltage value of the plurality of cells.

### BRIEF DESCRIPTION OF THE DRAWINGS

The above and other features of the present disclosure will now be described in detail with reference to one or more example embodiments of thereof illustrated the accompanying drawings which are given hereinafter by way of illustration only, and thus are not limitative of the present disclosure, and wherein:

FIG. 1 is a graph illustrating a current-voltage characteristic of a fuel cell stack;

FIG. 2 is a block diagram showing an available power output determination apparatus of a fuel cell stack;

FIG. 3 is a graph illustrating a method of determining variable parameters of a current-voltage characteristic model of a fuel cell stack;

FIG. 4 is a graph showing an available current value that varies according to a voltage drop;

FIG. 5 is a flowchart illustrating a method of determining parameters of a current-voltage characteristic model of a fuel cell stack; and

FIG. 6 is a flowchart illustrating a method of determining an available power output of a fuel cell stack.

FIG. 7 shows an example computing system.

It should be understood that the appended drawings are not necessarily to scale, presenting a somewhat simplified representation of various preferred features illustrative of the basic principles of the disclosure. The specific design features of the present disclosure as disclosed herein, including, for example, specific dimensions, orientations, locations, and shapes will be determined in part by the particular intended application and use environment.

In the figures, reference numbers refer to the same or equivalent parts of the present disclosure throughout the several figures of the drawing.

### DETAILED DESCRIPTION

Hereinafter, reference will be made in detail to various example embodiments of the present disclosure, examples of which are illustrated in the accompanying drawings and described below. While the disclosure will be described in conjunction with example embodiments, it will be understood that present description is not intended to limit the disclosure to the example embodiments. On the contrary, the disclosure is intended to cover not only the example embodiments, but also various alternatives, modifications, equivalents and other embodiments, which may be included within the spirit and scope of the disclosure as defined by the appended claims.

Terms such as “unit”, “module” and the like disclosed in the specification refer to a unit that handles at least one function or operation, which may be implemented as hardware or software or a combination of hardware and software. Throughout the present disclosure, references to components, units, or modules generally refer to items that logically can be grouped together to perform a function or group of related functions. Like reference numerals are generally intended to refer to the same or similar components. Components, units, and modules may be implemented in software, hardware or a combination of software and hardware. The components, units, modules, and/or functions described above may be implemented and/or performed by one or more processors. For examples, the components, units, and/or modules may include processor(s), microprocessor(s), graphics processing unit(s), logic circuit(s), dedicated circuit(s), application-specific integrated circuit(s), programmable array logic, field-programmable gate array(s), controller(s), microcontroller(s), and/or other suitable hardware. The components, units, and/or modules may also include software control module(s) implemented with a processor or logic circuitry for example. The components, units, and/or modules may include or otherwise be able to access memory such as, for example, one or more non-transitory computer-readable storage media, such as random-access memory, read-only memory, electrically erasable programmable read-only memory, erasable programmable read-only memory, flash/other memory device(s), data registrar(s), database(s), and/or other suitable hardware. One or more storage type media may include any or all of the tangible memory of computers, processors, or the like, or associated modules thereof, such as various semiconductor memories, tape drives, disk drives and the like, which may provide non-transitory storage at any time for software programming.

In addition, it will be understood that, although terms “first”, “second”, etc. may be used herein to describe various elements, these elements should not be limited by these terms.

For purposes of this application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as “A, B, or C”, “at least one of A, B, and C”, “at least one of A, B, or C”, etc. as used herein may mean each listed item or all possible combinations of the listed items. For example, “at least one of A or B” may refer to (1) at least one A; (2) at least one B; or (3) at least one A and at least one B.

The detailed description is merely exemplary. Further, the description is intended to illustrate example embodiments of the present disclosure, and the present disclosure may be used in various other combinations, modifications, and environments. That is, changes or modifications may be made within the scope of the concepts disclosed in this specification, within the scope equivalent to the disclosed content, and/or within the scope of technology or knowledge in the art. The described example embodiments illustrate implantation of the technical ideas of the present disclosure, and various changes required for specific application fields and uses of the present disclosure are also possible. Accordingly, the detailed description of the disclosure is not intended to limit the disclosure to the disclosed example embodiments. Further, the appended claims should be construed to include other embodiments as well.

FIG. 1 is a graph illustrating a current-voltage characteristic of an example fuel cell stack. Referring to FIG. 1, the horizontal axis represents current density (mA/cm²), and the vertical axis represents cell voltage (V). A total voltage loss of a fuel cell stack during operation may include various components. The voltage loss may include, for example, activation loss, ohmic loss, and/or concentration loss. Energy higher than activation energy must be applied to a chemical reaction, but the activation loss is a loss caused by the activation energy that occurs at a beginning stage of a basic chemical reaction of the fuel cell stack. The ohmic loss may be caused by transfer of charges that occurs in the components of the fuel cell stack. In this case, the greater the current applied to the fuel cell stack, the greater the transfer of charges may be, and thus, the greater the resistance. The concentration loss may be generated in a section in the graph where the voltage decreases because the amount of hydrogen moving, as the current applied to the fuel cell stack increases and the amount of hydrogen necessary for the chemical reaction increases, along a concentration gradient does not satisfy the demand. The concentration loss may occur in a section associated with a very high current density, which is a section outside an actual use area of the fuel cell stack. Thus, the concentration loss may not be considered in a process of determining the resistance loss of the fuel cell stack.

In order to distinguish these voltage loss components and the respective resistance components, the resistance measurement using the alternating impedance is widely used, but it takes a lot of time to measure the impedance of broadband (e.g., tens of kHz to several MHz), and to perform equivalent circuit modeling and nonlinear analysis. In addition, in order to measure the resistance components of the respective cells that form the stack using the impedance measurement, it may be necessary to individually test all the cells in sequence or to provide a device for simultaneously inputting alternating currents corresponding to the number of cells to be measured, which complicates the configuration of the device and increases the cost.

An operating process of the fuel cell stack may be necessary for normal operation of the fuel cell stack. A State-of-Health (SoH) of the fuel cell stack may be determined using current and voltage monitored during the operation of the fuel cell stack. On the basis of the measured SoH of the fuel cell stack, a current current-voltage state of the fuel cell stack may be estimated, and an available power output of the fuel cell stack at a preset reference voltage may be estimated. However, under a situation that does not follow a normal current-voltage estimation curve, such as cold starting, it is difficult to accurately estimate the current and voltage of the fuel cell stack. In addition, in a case where there is an abnormal voltage drop for some cells of the fuel cell stack, it may be difficult to determine a current state of the fuel cell stack to determine a precise available power output.

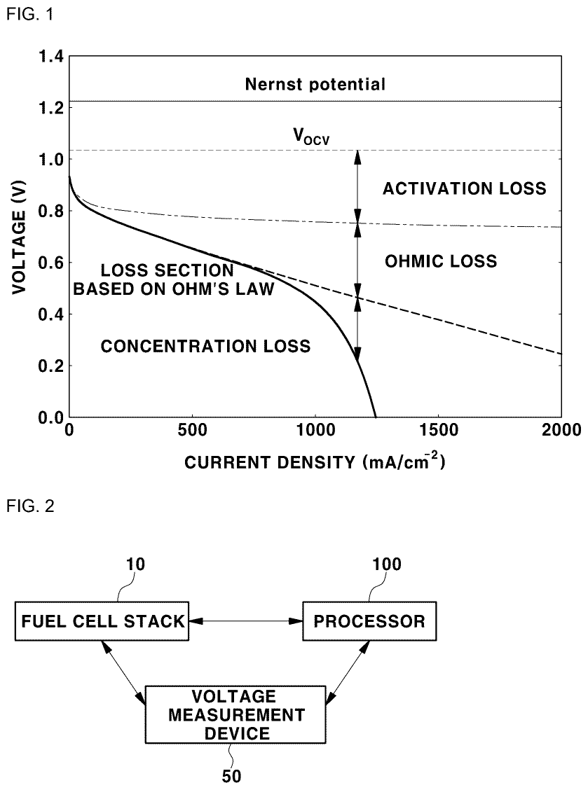

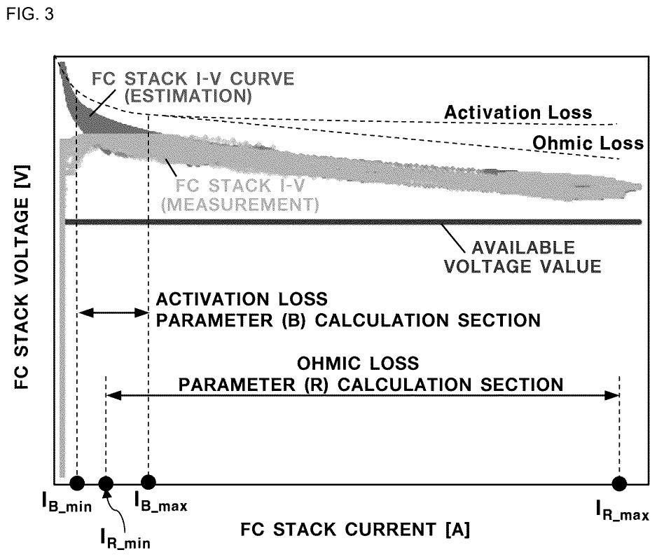

FIG. 2 is a block diagram showing an available power output determination apparatus of a fuel cell stack. FIG. 3 is a graph illustrating a method of determining variable parameters of a current-voltage characteristic model of a fuel cell stack.

Referring to FIGS. 2 and 3, a fuel cell stack 10 may include a plurality of cells. A processor 100 may estimate a voltage loss for each of the plurality of cells constituting the fuel cell stack 10 in real time. As used herein, the term “in real-time” may refer to a requirement to process data “without a significant delay,” for example, processing the data within a predetermined time constraint. This may be achieved, for example, by processing data without storing (e.g., permanent or long-term storage) intermediately produced result values. The processor 100 may estimate the voltage loss for each of the plurality of cells in real time using a current-voltage characteristic model. The current-voltage characteristic model may have at least one parameter.

The processor 100 may be a fuel cell control unit (FCU) for controlling the fuel cell stack 10. The processor 100 may include a memory. The processor 100 may include one or more cores, and may include a processor for data analysis and deep learning, such as a central processing unit (CPU), a general purpose graphics processing unit (GPGPU), a tensor processing unit (TPU), an application processor (AP), or the like. One or more processors 100 may process input data in accordance with a predefined operating rule or artificial intelligence model stored in the memory. In a case where one or more processors 100 are dedicated to artificial intelligence, the artificial intelligence dedicated processors may be designed with a hardware structure that is specialized for processing of a specific artificial intelligence model.

The processor 100 may read a computer program or instructions stored in the memory to control a fuel cell voltage and determine an available power output of the fuel cell stack. The memory may store a variety of information and maps necessary for the control of the fuel cell voltage and the determination of the available power output of the fuel cell stack. The memory may include at least one storage medium among a flash memory, a hard disk, a multimedia card micro type memory, a card type memory (for example, SD, XD memory or the like), a random access memory (RAM), a static random access memory (SRAM), a read-only memory (ROM), an electrically erasable programmable read-only memory (EEPROM), a programmable rear-only memory (PROM), a magnetic memory, a magnetic disk, and an optical disc. The memory may also include any form of computer readable recording medium well known in the art to which the present disclosure belongs. The above-mentioned memories are merely exemplary, and the present disclosure is not limited thereto.

The processor 100 may determine parameters by substituting (e.g., applying) current and voltage values of the fuel cell stack 10, which are measured in real time during operation of the fuel cell stack 10, into the current-voltage characteristic model.

A voltage measurement device (e.g., a voltmeter) 50 may measure the voltage of the fuel cell stack 10. For example, the voltage measurement device 50 may be a stack cell voltage monitoring unit (SVM). As an example, the voltage measurement device 50 may measure a voltage of all cells in the fuel cell stack 10 and a voltage of each cell in real time. As another example, the voltage measurement device 50 may measure a voltage of each of groups including two to four cells among the cells of the fuel cell stack 10.

The processor 100 may determine an average voltage value of all the cells constituting the fuel cell stack 10 and a minimum voltage value that is a minimum value among respective voltage values of all the cells or respective voltage values of plural groups including two or more cells during operation of the fuel cell stack 10 on the basis of data measured by the voltage measurement device 50. In addition, the processor 100 may measure a current value corresponding to the average voltage value or the minimum voltage value. The processor 100 may determine a first parameter by substituting (e.g., applying) the current values corresponding to the average voltage value and the average voltage value into the current-voltage characteristic model. In addition, the processor 100 may determine a second parameter by substituting (e.g., applying) the current values corresponding to the minimum voltage value and the minimum voltage value into the current-voltage characteristic model.

The voltage loss generated in the fuel cell stack 10 may include an activation loss, an ohmic loss, and a concentration loss. Here, the concentration loss may be a loss that does not occur in an actual use area of the fuel cell stack 10, and an open circuit voltage (OCV) of each cell may be a constant that is a fixed value. For example, the open circuit voltage of each cell may be about 1V. Further, the voltage applied to the fuel cell stack 10 and a current change according to the voltage may be measured in real time. The current-voltage characteristic model may be simplified as described below. In other words, the current-voltage characteristic model may be represented as the following expression (e.g., equation).

$$V = {V}_{ocv} - B \times In ( I ) - R \times I$$

In the expression, V may represent a voltage (e.g., available current), V_{ocv} may represent a constant, B may represent an activation loss parameter, I may represent a current, and R may represent an ohmic loss parameter. Initial values of the activation loss parameter and the ohmic loss parameter may be determined empirically (e.g., based on historical data).

The processor 100 may determine the activation loss parameter or the ohmic loss parameter on the basis of a range of current values measured in real time. An expression for determining the activation loss parameter may use the ohmic loss parameter as a variable. An expression for determining the ohmic loss parameter may use the activation loss parameter as a variable. In the process of determining the activation loss parameter or the ohmic loss parameter, the processor 100 may use a pre-determined activation loss parameter or ohmic loss parameter. For example, in a case where the pre-determined activation loss parameter exists during the determination of the ohmic loss parameter, the processor 100 may determine the ohmic loss parameter by substituting (e.g., applying) the pre-determined activation loss parameter, a current value and a voltage value measured in real time into the expression for determining the ohmic loss parameter.

The processor 100 may determine the activation loss parameter to obtain the activation loss that occurs in a first section. The first section may be a low-current section, which may be a section where current values are between I_{B_min} and I_{B_max}. Here, I_{B_min} may represent a point where a current change rate in B×In(I) is extremely large (e.g., above a predetermined threshold). In other words, I_{B_min} may be a point where the current change rate in B×In(I) is equal to or greater than a first specific (e.g., threshold) value. For example, I_{B_min} may be about 10A, which may vary depending on the specifications of the fuel cell stack 10 or a designer's setting. I_{B_max} may be a point where the current change rate in B×In(I) is not large (e.g., below a predetermined threshold). In other words, I_{B_max} may be a point where the current change rate in B×In(I) is less than a second specific (e.g., threshold) value. The first specific value may be greater than the second specific value. In sections outside of the low-current section, the activation loss may rarely change (e.g., change at a much slower rate than in the low-current section). The expression (e.g., equation) for determining the activation loss parameter may be expressed as follows:

$$B = \frac{{V}_{OCV} - V - R \times I}{ln ( I )}$$

The processor 100 may determine the activation loss parameter by substituting (e.g., applying) the current value and the voltage value of the fuel cell stack 10 measured in real time in the first section into the current-voltage characteristic model. In order to determine the activation loss parameter in the first section, the processor 100 may determine the ohmic loss parameter as an initial value.

The processor 100 may determine the ohmic loss parameter after determining the activation loss parameter, to determine the ohmic loss that occurs in a second section. The second section may be a normal current section, and the ohmic loss in the normal current section decline substantially linearly. For example, the second section may be a current section after the first section (e.g., the second section may begin where the first section ends on the graph shown in FIG. 3), but the first section and the second section may partially overlap. In other words, the first section may be a section in which the activation loss mainly occurs, and the second section may be a section in which the ohmic loss mainly occurs and is reduced linearly. The expression (e.g., equation) for determining the ohmic loss parameter may be expressed as follows:

$$R = \frac{{V}_{OCV} - V - B \times ln I}{I}$$

The activation loss parameter in the second section may be a specific value of the activation loss parameter determined in the first section. That is, the processor 100 may determine the ohmic loss parameter by substituting (e.g., applying) the activation loss parameter determined in the first section, and the current value and the voltage value measured in real time into the current-voltage characteristic model.

For example, in a case where the current value of the fuel cell stack 10 is a value in the first section (e.g., if the current value is between I_{B_min} and I_{R_min}), other than the section where the first and second sections overlap, the processor 100 may determine the ohmic loss parameter as an initial value. The processor 100 may determine the activation loss parameter by substituting (e.g., applying) the current and voltage values measured in real time into the current-voltage characteristic model. That is, the processor 100 may not perform the process of determining the ohmic loss parameter. However, during the determination of the activation loss parameter, in a case where information on the previously determined ohmic loss parameter exists, the processor 100 may determine the activation loss parameter using the previously determined ohmic loss parameter.

For example, in a case where the current value of the fuel cell stack 10 is a value in the section where the first and second sections overlap (e.g., the current value is between I_{R_min} and I_{B_max}), the processor 100 may determine the ohmic loss parameter as an initial value, and may determine the activation loss parameter by substituting (e.g., applying) the current and voltage values measured in real time into the current-voltage characteristic model. I_{R_min} may be defined as a value between I_{B_min} and I_{B_max}. That is, a first minimum current value (I_{B_min}) of the low current section is less than a second minimum current value (I_{R_min}) of the normal current section. The processor 100 may determine the ohmic loss parameter by substituting (e.g., applying) the determined activation loss parameter, and the current value and the voltage value measured in real time into the current-voltage characteristic model. That is, the processor 100 may determine both the activation loss parameter and the ohmic loss parameter using one current value and one voltage value measured in real time.

For example, in a case where the current value of the fuel cell stack 10 is a value in the second section (e.g., the current value is between I_{B_max} and I_{R_max}), other than the section where the first and second sections overlap, the processor 100 may determine the ohmic loss parameter by substituting (e.g., applying) the previously determined activation loss parameter, and the current and voltage values measured in real time into the current-voltage characteristic model. The previously determined activation loss parameter may be the activation loss parameter determined in a case where the current value of the fuel cell stack 10 measured in real time is a value in the first section.

In the process of operating the fuel cell stack 10, the voltage value applied to the fuel cell stack 10 and the current value of the fuel cell stack 10 may vary. Depending on the voltage and current values that change in real time, the activation loss parameters and the ohmic loss parameters may also vary. As performance is restored by the temperature increase of the fuel cell stack 10, the phenomenon of linear reduction of the ohmic loss parameter may become apparent.

For example, the processor 100 may perform the process of determining the activation loss parameter and the ohmic loss parameter for each of the average voltage value and the minimum voltage value determined on the basis of the voltage measured in real time. The processor 100 may determine a first activation loss parameter and a first ohmic loss parameter using the average voltage value and the current value corresponding thereto. The processor 100 may determine a second activation loss parameter and a second ohmic loss parameter using the minimum voltage value and the current value corresponding the minimum voltage value.

The activation loss parameter and the ohmic loss parameter may be updated according to the voltage value and the current value changing in real time, and the reliability of estimating a current-voltage curve of the fuel cell stack 10 may be improved by using the current-voltage characteristic model with the updated activation loss parameter and ohmic loss parameter applied.

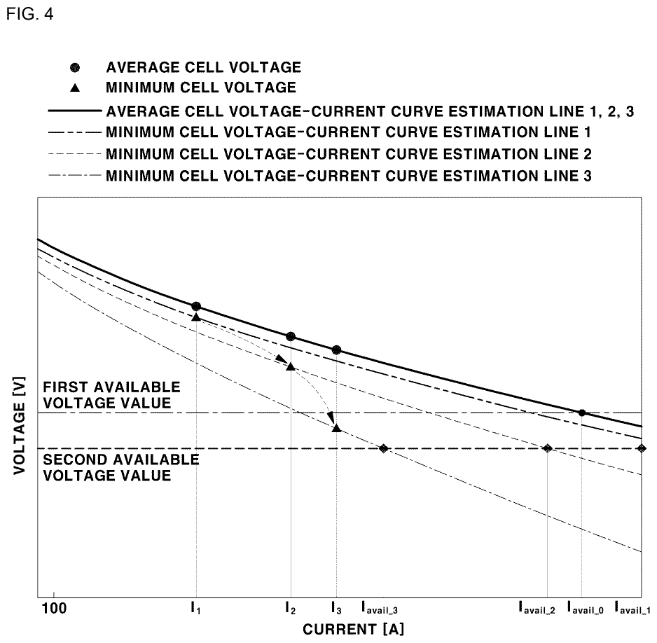

FIG. 4 is a graph showing an available current value that varies according to a voltage drop, which shows voltage-current curve estimation lines according to an average voltage value and a minimum voltage value of a fuel cell stack. Here, voltage-current curve estimation lines 1 to 3 according to the average voltage value of the fuel cell stack are shown as one line due to the small amount of change therebetween.

Referring to FIGS. 2 and 4, the processor 100 may determine the available power output of the fuel cell stack 10 using the determined parameters. The processor 100 may apply the activation loss parameter and the ohmic loss parameter to the current-voltage characteristic model, and may determine an available current value in a case where the fuel cell stack 10 reaches an available voltage value in an available state in the current-voltage characteristic model. The available voltage value may be defined as the smallest voltage value among voltage values in a state where the fuel cell stack 10 is available. The available current value of the fuel cell stack 10 may be a value obtained by predicting the current value of the fuel cell stack 10 in reaching the available voltage value on the basis of the current-voltage characteristic model with continuously updated parameters applied. The voltage-current curve estimation lines in FIG. 4 may be derived according to the current-voltage characteristic model with the continuously updated parameters applied.

The processor 100 may perform linearization for the current-voltage characteristic model on the basis of each of a plurality of empirical experimental current values (e.g., historical current values). The linearization for the current-voltage characteristic model may refer to applying the Taylor series to an expression representing a current-voltage characteristic model including a logarithmic function. In the process of linearizing the current-voltage characteristic model, certain empirical current values may be used. For example, the empirical (e.g., historical) current values may be 50A, 100A, 150A, and 250A, without being specifically limited to such values.

For example, the current-voltage characteristic model linearized by applying a primary Taylor series to the empirical (e.g., historical) current value of 250A may be represented as follows:

$$V = {V}_{OCV} - B \times ( ln 250 + \frac{I - 250}{250} ) - R \times I$$

An expression for the available current value in the available voltage value of the fuel cell stack 10 using the linearized expression (e.g., equation) may be represented as follows:

$${I}_{avail} = \frac{{V}_{OCV} - {V}_{avail \_ min} - B ( ln 250 - 1 )}{R + \frac{B}{250}}$$

Here, Iₐᵥₐᵢₗ may be an available current value, and V_{avail_min} may be an available voltage value. The processor 100 may determine one or more preliminary (e.g., pre-available) current values through the linearized current-voltage characteristic model by applying the primary Taylor series to each of the plural empirical (e.g., historical) current values.

Based on historical data, the available current value representing the closest approximation to an actual available current value on the basis of the voltage-current characteristic model is the maximum value of the preliminary current values determined on the basis of the respective empirical (e.g., historical) current values. The processor 100 may determine the one or more preliminary current values by substituting (e.g., applying) the available voltage value, which is the minimum voltage value with the fuel cell stack 10 available, into the linearized current-voltage characteristic model for each of the empirical (e.g., historical) current values. Here, the current-voltage characteristic model may refer to a model to which the updated parameters are applied. The processor 100 may finally determine the maximum value among the one or more preliminary current values as the available current value for determining the available power output of the fuel cell stack 10. For example, the processor 100 may determine the available current values Iₐᵥₐᵢₗ for the respective empirical (e.g., historical) current values of 50A, 100A, 150A, and 250A, and may determine the maximum value among the one or more available current values Iₐᵥₐᵢₗ as the final available current value.

For example, the processor 100 may determine the average voltage value and the minimum voltage value on the basis of data measured by the voltage measurement device 50, and may determine in advance a first available voltage value, which is the available voltage value according to the average voltage value, and a second available voltage value, which is the available voltage value according to the minimum voltage value. In this case, the second available voltage value may be smaller than the first available voltage value. In the case of the current-voltage characteristic model derived by a minimum voltage value of a specific cell, a lower available voltage value may be used to apply a relatively relaxed reference thereto.

The processor 100 may derive the first parameter by applying the average voltage value and the current value corresponding thereto to the current-voltage characteristic model. The processor 100 may perform linearization for the current-voltage characteristic model to which the first parameter is applied, and may determine one or more first preliminary current values by substituting (e.g., applying) the first available voltage value into the current-voltage characteristic model linearized by applying the primary Taylor series to each of the one or more empirical (e.g., historical) current values. The processor 100 may determine the maximum value among the one or more first preliminary current values as a first available current value. The processor 100 may determine a second parameter by applying the minimum voltage value and the current value corresponding thereto to the current-voltage characteristic model. The processor 100 may perform linearization for the current-voltage characteristic model to which the second parameter is applied, and may determine one or more second preliminary current values by substituting (e.g., applying) the second available voltage value into the current-voltage characteristic model linearized by applying the primary Taylor series to each of the one or more empirical (e.g., historical) current values. The processor 100 may determine the maximum value among the one or more second preliminary current values as a second available current value.

As an example, in a case where an abnormal voltage drop occurs in some of the cells of the fuel cell stack 10, the current value of the fuel cell stack 10 may gradually increase from I1 to I2 and from I2 to I3. Here, the voltage value of the fuel cell stack 10 may be reduced. However, since a minimum voltage value of the fuel cell stack 10 is a voltage value of a cell where the abnormal voltage drop occurs, a reduction width of the minimum voltage value of the fuel cell stack 10 may be larger than a reduction width of the average voltage value of the fuel cell stack 10. While the current value of the fuel cell stack 10 increases from I1 to I3, the first and second parameters according to the average voltage value and the minimum voltage value of the fuel cell stack 10 may be updated in real time. Thus, for three respective current values, three voltage-current estimation lines for the average voltage values of the fuel cell stack 10 may be derived, and for three current values, three voltage-current estimation lines for the minimum voltage values of the fuel cell stack 10 may be derived. In a case where the current value of the fuel cell stack 10 increases from I1 to I3, points at which the voltage-current curve estimation lines derived according to the average voltage values of the fuel cell stack 10 and the first available voltage value meet may represent three values with no significant change with reference to I_{available_0}. In a case where the current value of the fuel cell stack 10 increases from I1 to I3, points at which the voltage-current curve estimation lines derived according to the minimum voltage values of the fuel cell stack 10 and the second available voltage value meet may be I_{avail_1}, I_{avail_2}, and I_{avail_3}. As a result, as the current value of the fuel cell stack 10 increases from I1 to I3, the first available current value (I_{avail_0}) may not change significantly, but the second available current values (I_{avail_1}, I_{avail_2}, and I_{avail_3}) may gradually decrease. Thus, in a case where the abnormal voltage drop occurs in some of the cells of the fuel cell stack 10, the processor 100 may determine a relatively low available power output by reflecting the second available current values (I_{avail_1}, I_{avail_2}, and I_{avail_3}) in consideration of a state of the abnormal cell.

The processor 100 may update the first and second parameters on the basis of the current and voltage values of the fuel cell stack 10, which are measured in real time, and may continuously determine the available current values using the current-voltage characteristic model to which the updated parameters are applied. The processor 100 may determine new first and second available current values in a case where the activation loss parameter and the ohmic loss parameter are updated.

The control unit 100 may determine the available power output of the fuel cell stack 10 by multiplying the available voltage value by the available current value. As the current and voltage values measured in real time during the operation process of the fuel cell stack 10 vary, the parameters may vary, and thus, the available current value and the available power output may be increased. The operating process of the fuel cell stack 10 may include a heating process of the fuel cell stack 10.

It is possible to improve the reliability of estimating the current-voltage curve of the fuel cell stack 10 by using the current-voltage characteristic model to which the activation loss parameter and the ohmic loss parameter that vary in accordance with the voltage value and the current value changing in real time are applied. Thus, it is possible to improve the reliability of predicting the available power output of the fuel cell stack 10.

As the parameter determination and the current-voltage curve estimation are performed according to the voltage values for some cells in the fuel cell stack 10, it is possible to determine the available power output of the fuel cell stack 10 in consideration of the state of the cells representing the abnormal voltage drop.

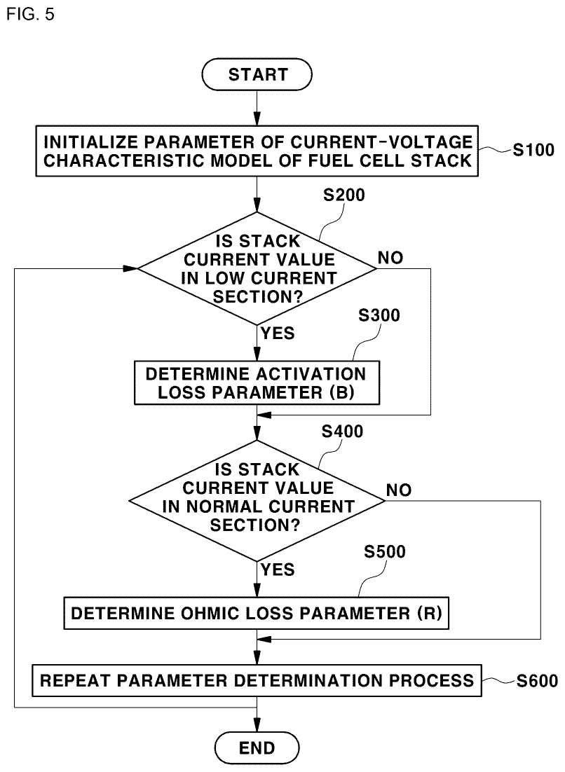

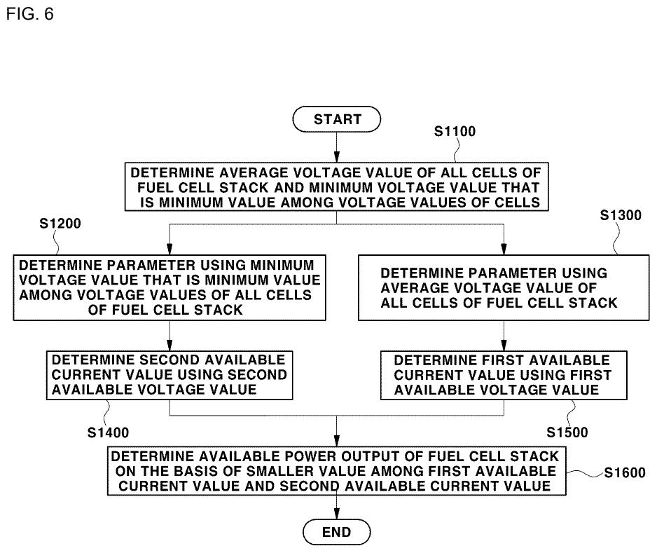

FIG. 5 is a flowchart illustrating a method of determining parameters of a current-voltage characteristic model of a fuel cell stack. One or more steps of the example method(s) of FIGS. 5-6 may be omitted, performed in other orders, and/or otherwise modified, and/or one or more additional steps may be added.

Referring to FIG. 5, the current-voltage characteristic model of the fuel cell stack may be constructed, and at least one parameter applied to the current-voltage characteristic model may be initialized. In the current-voltage characteristic model, the activation-loss parameter and the ohmic-loss parameter may be applied, and a predetermined initial value for each of the activation loss parameter and the ohmic loss parameter may be determined (S100).

The current and voltage values of the fuel cell stack may be monitored in real time. For example, the voltage measurement device may measure an average voltage of all cells constituting the fuel cell stack or a voltage of each of the cells. The processor may determine whether the current value of the fuel cell stack is in a low current section. In a case where the current value of the fuel cell stack is not in the low current section, the processor may determine whether the current value of the fuel cell stack is in a normal current section (S200).

In a case where the current value of the fuel cell stack is in the low current section, the processor may determine the activation loss parameter by substituting (e.g., applying) the current and voltage values measured in real time and an initial value of the ohmic loss parameter into the current-voltage characteristic model. However, in a case where the current value of the fuel cell stack measured in the previous cycle is in the normal current section and there is already a determination history of the ohmic loss parameter, the processor may determine the activation loss parameter by substituting (e.g., applying) the current value and voltage value measured in real time and the ohmic loss parameter determined in the previous cycle into the current-voltage characteristic model (S300).

The processor may determine whether the current value of the fuel cell stack is in the normal current section. In a case where the current value of the fuel cell stack is not in the normal current section, the processor may determine whether the current value of the fuel cell stack is in the low current section (S400).

In a case where the current value of the fuel cell stack is in the normal current section, the processor may determine the ohmic loss parameter by substituting (e.g., applying) the current and voltage values measured in real time and an initial value of the activation loss parameter determined in the previous cycle into the current-voltage characteristic model. However, in a case where the activation loss parameter determined in the previous cycle does not exist, the processor may determine the ohmic loss parameter using the initial value of the activation loss parameter. However, during the operation of the fuel cell stack 10 in cold starting, the current value tends to increase continuously, and thus, in a case where the current value of the fuel cell stack measured in real time is in the normal current section, the activation loss parameter may be determined in advance (S500).

The processor may apply the determined activation loss parameter and the ohmic loss parameter to the current-voltage characteristic model. During the operation of the fuel cell stack, the voltage measurement device may measure the voltage and current values of the fuel cell stack in real time, and the processor may repeatedly perform the process of determining the activation loss parameter and the ohmic loss parameter using the measured voltage and current values (S600).

FIG. 6 is a flowchart illustrating a method of determining an available power output of a fuel cell stack. For the sake of brevity, redundant description is omitted.

Referring to FIG. 6, the voltage measurement device may measure voltage and current values of the fuel cell stack in real time. The voltage measurement device may measure an average voltage of all cells that form the fuel cell stack, a voltage of each of the cells that form the fuel cell stack, and a voltage of each of one or more groups including two or more cells that form the fuel cell stack. On the basis of data measured by the voltage measurement device, the processor may determine the average voltage value of all the cells that form the fuel cell stack, and a minimum voltage value that is a minimum value among the voltage values of the cells constituting the fuel cell stack or the voltage values of the one or more groups including two or more cells of the cells that form the fuel cell stack (S1100).

The processor may determine a first parameter by substituting (e.g., applying) the average voltage value into a current-voltage characteristic model of the fuel cell stack having at least one parameter. The first parameter may include a first activation loss parameter and a first ohmic loss parameter. The processor may determine the first activation loss parameter by substituting (e.g., applying) a current value which is measured in a low current section for the first activation loss parameter and the average voltage value into the current-voltage characteristic model. The processor may determine the first ohmic loss parameter by substituting (e.g., applying) the current value measured in a normal current section for the first ohmic loss parameter and the average voltage value into the current-voltage characteristic model (S1200).

The processor may determine a second parameter by substituting (e.g., applying) the minimum voltage value into the current-voltage characteristic model of the fuel cell stack having at least one parameter. The second parameter may include a second activation loss parameter and a second ohmic loss parameter. The processor may determine the second activation loss parameter by substituting (e.g., applying) the current value measured in the low current section for the second activation loss parameter and the minimum voltage value into the current-voltage characteristic model. The processor may determine the second ohmic loss parameter by substituting (e.g., applying) the current value measured in the normal current section for the second ohmic loss parameter and the minimum voltage value into the current-voltage characteristic model (S1300).

The processor may determine a first available current value by substituting (e.g., applying) a predetermined first available voltage value into the current-voltage characteristic model to which the first parameter is applied. Specifically, the processor may perform linearization of the current-voltage characteristic model to which the first parameter is applied using a plurality of empirical (e.g., historical) current values. The processor may determine a maximum value among one or more first preliminary current values determined by substituting (e.g., applying) the first available voltage value into the current-voltage characteristic models linearized for the respective empirical (e.g., historical) current values as a first available current value (S1400).

The processor may determine a second available current value by substituting (e.g., applying) a predetermined second available voltage value into the current-voltage characteristic model to which the second parameter is applied. Specifically, the processor may perform linearization of the current-voltage characteristic model to which the second parameter is applied using a plurality of empirical (e.g., historical) current values. The processor may determine a maximum value among one or more second preliminary current values determined by substituting (e.g., applying) the second available voltage value into the current-voltage characteristic models linearized for the respective empirical (e.g., historical) current values as a second available current value (S1500).

The processor may determine an available power output of the fuel cell stack on the basis of a smaller (e.g., lesser) value among the first available current value and the second available current value. The processor may determine the available power output of the fuel cell stack by multiplying the smaller value among the first and second available current values by an available voltage value corresponding to the smaller value. For example, in a case where the smaller value among the first and second available current values is the first available current value, the processor may determine the available power output of the fuel cell stack by multiplying the first available current value by the first available voltage value (S1600).

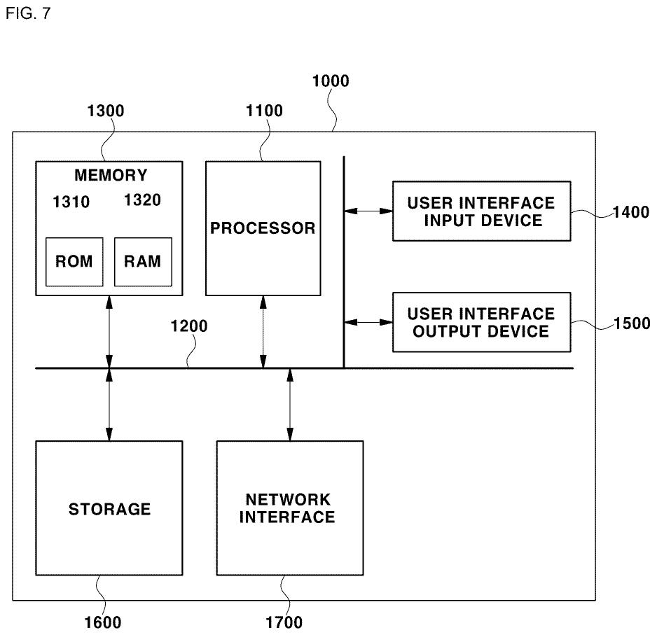

FIG. 7 shows an example computing system (e.g., a computing device of a vehicle or any other apparatus). One or more controllers, processors, etc. described herein, such as the fuel cell stack 10, the voltage measurement device 50, the processor 100, and any other components and devices disclosed herein, may be implemented by or in the computing system as shown in FIG. 7.

A computing system 1000 may include at least one processor 1100, memory 1300, a user interface input device 1400, a user interface output device 1500, a storage 1600, and a network interface 1700, which are connected with each other via a bus 1200.

The processor 1100 may be a central processing unit (CPU) or a semiconductor device that processes instructions stored in the memory 1300 and/or the storage 1600. Each of the memory 1300 and the storage 1600 may include various types of volatile or nonvolatile storage media. For example, the memory 1300 may include a read-only memory (ROM) and a random-access memory (RAM).

Communication interface(s) (also referred to as communication device(s), communicator(s), communication module(s), communication unit(s), etc.), such as the network interface 1700, may allow software and/or data to be transferred between a device and one or more external devices, and/or between one or more components of a device. Communication interface(s) may include a receiver, a transmitter, a transceiver, a modem, a network interface and/or adapter (such as an Ethernet adapter), a radio transceiver, an antenna, a communication port, a Personal Computer Memory Card International Association (PCMCIA) slot and card, or the like. Software and data transferred via communication interface(s) may be in the form of signals, which may be electronic, electromagnetic, optical, infrared, or other signals capable of being received by communication interface(s). These signals may be provided to communication interface(s) via a communication path of a device, which may be implemented using, for example, wire or cable, fiber optics, a cellular link, a radio frequency (RF) link and/or other communications channels. Communication interface(s) may communicate using one or more communication protocols, such as Ethernet, Wi-Fi, near-field communication (NFC), Infrared Data Association (IrDA), Bluetooth, Bluetooth low energy (BLE), Zigbee, Long-Term Evolution (LTE), 5G New Radio (NR), vehicle-to-everything (V2X), a controller area network (CAN), or a local interconnect network (LIN), etc.

Accordingly, the operations of the method or algorithm described in connection with example embodiment(s) disclosed in the specification may be directly implemented with a hardware module, a software module, or a combination of the hardware module and the software module, which is executed by the processor 1100. The software module may reside on a storage medium (e.g., the memory 1300 and/or the storage 1600) such as RAM, a flash memory, ROM, an erasable and programmable ROM (EPROM), an electrically EPROM (EEPROM), a register, a hard disk drive, a removable disc, or a compact disc-ROM (CD-ROM).

The storage medium may be coupled to the processor 1100. The processor 1100 may read out information from the storage medium and may write information in the storage medium. Alternatively, the storage medium may be integrated with the processor 1100. The processor and storage medium may be implemented with an application specific integrated circuit (ASIC). The ASIC may be provided in a user terminal. Alternatively, the processor and storage medium may be implemented with separate components in the user terminal.

In one aspect, the present disclosure provides an available power output determination apparatus of a fuel cell stack including a processor that determines an available power output of the fuel cell stack using a current-voltage characteristic model of the fuel cell stack having at least one parameter, in which the processor determines the parameter by substituting current and voltage values of the fuel cell stack measured in real time during operation of the fuel cell stack into the current-voltage characteristic model, and determines the available power output of the fuel cell stack using the current-voltage characteristic model to which the parameter is applied and an available voltage value while the fuel cell stack is available. The voltage value includes at least one of an average voltage value of all cells constituting the fuel cell stack and a minimum voltage value that is a minimum value among voltage values of all the cells.

The available voltage value may include a first available voltage value that is applied to the current-voltage characteristic model in a case where the available power output is determined using the average voltage value, and a second available voltage value that is applied to the current-voltage characteristic model in a case where the available power output is determined using the minimum voltage value.

The processor may determine a first available current value of the fuel cell stack by substituting the first available voltage value into the current-voltage characteristic model to which the parameter determined on the basis of the average voltage value is applied, and may determine a second available current value of the fuel cell stack by substituting the second available voltage value into the current-voltage characteristic model to which the parameter determined on the basis of the minimum voltage value is applied.

The processor may determine the available power output of the fuel cell stack using a smaller value among the first available current value and the second available current value.

The parameter may include an activation loss parameter and an ohmic loss parameter.

The processor may determine the activation loss parameter by substituting a current value and a voltage value measured in a low current section for the activation loss parameter, and may determine the ohmic loss parameter by substituting a current value and a voltage value measured in a normal current section for the ohmic loss parameter.

An expression for determining the activation loss parameter may use the ohmic loss parameter as a variable, an expression for determining the ohmic loss parameter may use the activation loss parameter as a variable, and the activation loss parameter or the ohmic loss parameter that is pre-determined may be used in the process of determining the activation loss parameter or the ohmic loss parameter.

The current-voltage characteristic model may be represented as the following expression:

$$V = {V}_{ocv} - B \times In ( I ) - R \times I$$

where V_{ocv} represents a constant, B represents an activation loss parameter, and R represents an ohmic loss parameter.

The processor may perform linearization for the current-voltage characteristic model using the activation loss parameter, the ohmic loss parameter, and a plurality of experimental current values, and may determine a maximum value among a plurality of pre-available current values determined by substituting the available voltage value into the current-voltage characteristic models linearized for the respective experimental current values as an available current value.

In another aspect, the present disclosure provides an available power output determination method of a fuel cell stack including determining an average voltage value of all cells constituting the fuel cell stack and a minimum voltage value that is a minimum value among voltage values of all the cells or voltage values of groups including two or more cells in a process of operating the fuel cell stack, by a processor, determining a first parameter by substituting the average voltage value into a current-voltage characteristic model of the fuel cell stack having at least one parameter, and a second parameter by substituting the minimum voltage value into the current-voltage characteristic model, by the processor, and determining an available power output of the fuel cell stack using the current-voltage characteristic model, by the processor.

The first parameter and the second parameter may include an activation loss parameter and an ohmic loss parameter, respectively.

The determining the first parameter and the second parameter may include determining the activation loss parameters by respectively substituting the average voltage value and the minimum voltage value measured in a low current section into the current-voltage characteristic model, and determining the ohmic loss parameters by respectively substituting the average voltage value and the minimum voltage value measured in a normal current section into the current-voltage characteristic model.

The determining the available power output of the fuel cell stack may include determining a first available current value using the current-voltage characteristic model to which the first parameter is applied and a first available voltage value in a state where the fuel cell stack is available, and determining a second available current value using the current-voltage characteristic model to which the second parameter is applied and a second available voltage value in a state where the fuel cell stack is available.

The determining the available power output of the fuel cell stack further may include determining the available power output of the fuel cell stack using a smaller value among the first available current value and the second available current value.

The determining the available power output of the fuel cell stack may include performing linearization for the current-voltage characteristic model formed by an expression based on each of a plurality of experimental current values, determining a plurality of pre-available current values by substituting the first available voltage value and the second available voltage value in a state where the fuel cell stack is available into the current-voltage characteristic models linearized for the respective experimental current values, and determining a maximum value among the plural pre-available current values determined according to the first available voltage value as the first available current value and determining a maximum value among the plural pre-available current values determined according to the second available voltage value as the second available current value.

It may be possible to improve the reliability of estimating the current-voltage curve of the fuel cell stack by using the current-voltage characteristic model to which the activation loss parameter and the ohmic loss parameter that vary in accordance with the voltage value and the current value changing in real time are applied. Thus, it is possible to improve the reliability of predicting the available power output of the fuel cell stack.

As the parameter determination and the current-voltage curve estimation are performed according to the voltage values for some cells in the fuel cell stack, it is possible to determine the available power output of the fuel cell stack in consideration of the state of the cells representing the abnormal voltage drop.

The disclosure has been described in detail with reference to example embodiments thereof. However, it will be appreciated by those skilled in the art that changes may be made in these example embodiments without departing from the principles and spirit of the disclosure, the scope of which is defined in the appended claims and their equivalents.

What is claimed is:

1. An apparatus comprising:
a processor; and
a memory storing at least one instruction that is configured, when executed by the processor communicating with the memory, to cause the apparatus to:
measure, in real-time during an operation of a fuel cell stack comprising a plurality of cells, a current value and a voltage value associated with the fuel cell stack, wherein the voltage value comprises at least one of an average voltage value of the plurality of cells or a minimum voltage value of the plurality of cells;
determine at least one parameter of the fuel cell stack by applying the measured current value and the measured voltage value to a current-voltage characteristic model;
determine, based on applying the at least one parameter to the current-voltage characteristic model and based on an available voltage value of the fuel cell stack, an available power output of the fuel cell stack; and
control, based on the available power output of the fuel cell stack, an operation of the fuel stack.

2. The apparatus of claim 1, wherein the available voltage value comprises one of:
based on the available power output being determined using the average voltage value, a first available voltage value that is applied to the current-voltage characteristic model; or
based on the available power output being determined using the minimum voltage value, a second available voltage value that is applied to the current-voltage characteristic model.

3. The apparatus of claim 2, wherein the at least one instruction is configured, when executed by the processor communicating with the memory, to cause the apparatus to determine the available power output of the fuel cell stack by:
based on the at least one parameter being determined based on the average voltage value, determining a first available current value of the fuel cell stack by applying the first available voltage value to the current-voltage characteristic model; or
based on the at least one parameter being determined based on the minimum voltage value, determining a second available current value of the fuel cell stack by applying the second available voltage value to the current-voltage characteristic model.

4. The apparatus of claim 3, wherein the at least one instruction is configured, when executed by the processor communicating with the memory, to cause the apparatus to determine the available power output of the fuel cell stack by using a lesser value of the first available current value and the second available current value.

5. The apparatus of claim 1, wherein the at least one parameter comprises at least one of an activation loss parameter or an ohmic loss parameter.

6. The apparatus of claim 5, wherein the at least one instruction is configured, when executed by the processor communicating with the memory, to further cause the apparatus to:
determine the activation loss parameter by applying a first current value and a first voltage value that are measured in a low current section of the current-voltage characteristic model; and
determine the ohmic loss parameter by applying a second current value and a second voltage value that are measured in a normal current section of the current-voltage characteristic model, wherein a first minimum current value of the low current section is less than a second minimum current value of the normal current section.

7. The apparatus of claim 6, wherein an equation for determining the activation loss parameter uses a predetermined ohmic loss parameter as a variable, and
wherein an equation for determining the ohmic loss parameter uses a predetermined activation loss parameter as a variable.

8. The apparatus of claim 1, wherein the current-voltage characteristic model comprises an equation:
$$V = {V}_{ocv} - B \times In ( I ) - R \times I$$
where V represents the voltage value, V_{ocv} represents a constant, B represents an activation loss parameter, I represents the current value, and R represents an ohmic loss parameter.

9. The apparatus of claim 8, wherein the at least one instruction is configured, when executed by the processor communicating with the memory, to further cause the apparatus to:
based on the activation loss parameter, the ohmic loss parameter, and a plurality of historical current values, perform linearization of the current-voltage characteristic model; and
determine an available current value by determining a maximum value among a plurality of preliminary current values, wherein the plurality of preliminary current values are determined by applying the available voltage value to the linearized current-voltage characteristic model.

10. A method performed by an apparatus associated with a fuel cell stack, the method comprising:
measuring, via a voltage sensor and during an operation of the fuel cell stack, an average voltage value of a plurality of cells of the fuel cell stack and a minimum voltage value of at least two of the plurality of cells;
determining a first parameter of the fuel cell stack by applying the measured average voltage value to a current-voltage characteristic model of the fuel cell stack;
determining a second parameter of the fuel cell stack by applying the measured minimum voltage value to the current-voltage characteristic model;
identifying, based on at least one of the first parameter or the second parameter and based on the current-voltage characteristic model, an available power output of the fuel cell stack; and
controlling, based on the available power output of the fuel cell stack, an operation of the fuel cell stack.

11. The method of claim 10, wherein the first parameter and the second parameter include an activation loss parameter, and an ohmic loss parameter, respectively.

12. The method of claim 11, wherein the determining of the first parameter and the second parameter comprises:
determining the activation loss parameter by applying, to the current-voltage characteristic model, a first average voltage value and a first minimum voltage value that are measured in a low current section of the current-voltage characteristic model, and
determining the ohmic loss parameter by applying, to the current-voltage characteristic model, a second average voltage value and a second minimum voltage value that are measured in a normal current section of the current-voltage characteristic model, wherein a first minimum current value of the low current section is less than a second minimum current value of the normal current section.

13. The method of claim 10, wherein the determining of the available power output of the fuel cell stack comprises:
determining a first available current value of the fuel cell stack based on:
the current-voltage characteristic model, to which the first parameter is applied, and
a first available voltage value; and
determining a second available current value of the fuel cell stack based on:
the current-voltage characteristic model, to which the second parameter is applied, and
a second available voltage value.

14. The method of claim 13, wherein the determining of the available power output of the fuel cell stack further comprises:
determining the available power output of the fuel cell stack by using a lesser value of the first available current value and the second available current value.

15. The method of claim 13, wherein the determining of the available power output of the fuel cell stack further comprises:
performing, based on a plurality of historical current values, linearization of the current-voltage characteristic model;
determining a plurality of first preliminary current values by applying the first available voltage value to the linearized current-voltage characteristic model;
determining a plurality of second preliminary current values by applying the second available voltage value to the linearized current-voltage characteristic model;
determining the first available current value by determining a first maximum value among the plurality of first preliminary current values; and
determining the second available current value by determining a second maximum value among the plurality of the second preliminary current values.

16. A vehicle comprising:
at least one sensor comprising a voltage sensor;
a fuel cell stack comprising a plurality of cells;
a processor; and
a memory storing at least one instruction that is configured, when executed by the processor communicating with the memory, to cause the vehicle to:
measure, during an operation of the fuel cell stack, a current value and a voltage value associated with the fuel cell stack, wherein the voltage value comprises at least one of an average voltage value of the plurality of cells or a minimum voltage value of the plurality of cells;
determine at least one parameter of the fuel cell stack by applying the measured current value and the measured voltage value to a current-voltage characteristic model;
determine, based on applying the at least one parameter to the current-voltage characteristic model and based on an available voltage value of the fuel cell stack, an available power output of the fuel cell stack; and
control, based on the available power output of the fuel cell stack, an operation of the fuel cell stack.
